(19) United States
(12) Patent Application Publication
(10) Pub. No.: US 2015/0015269 A1
(43) Pub. Date: Jan. 15, 2015

(54) DETECTION OF MIS-SOLDERED CIRCUITS BY SIGNAL ECHO CHARACTERISTICS

(71) Applicant: NVIDIA CORPORATION, Santa Clara, CA (US)

(72) Inventors: Hans Wolfgang SCHULZE, Palo Alto, CA (US); Cameron BUSCHARDT, Round Rock, TX (US)

(21) Appl. No.: 13/940,164

(22) Filed: Jul. 11, 2013

(51) Int. Cl. G01R 31/303; G01R 31/28

(52) U.S. Cl. CPC G01R 31/303; G01R 31/2853
USPC 324/527

(57) ABSTRACT

One embodiment of the present invention sets forth a method for detecting defective solder balls that includes configuring a transmitter pad to transmit a pulse signal, transmitting the pulse signal, configuring transmitter pad to receive a pulse reflection, receiving a pulse reflection, analyzing the pulse reflection; and determining whether the pulse reflection is indicative of a defective solder ball. One advantage of the disclosed method is that solder ball defects may be detected more accurately than in the trial and error approach.

### BACKGROUND OF THE INVENTION

### Field of the Invention

Embodiments of the present invention generally relate to integrated circuit fabrication, and specifically, to the detection of mis-soldered circuits by signal echo characteristics.

Integrated circuits (ICs) are often composed of smaller devices that are attached to each other using “solder balls.” Solder balls are balls of solder that are placed on the ends of electrical connections. The purpose of solder balls is to connect devices to printed circuit board (PCB) wires to form an electrical connection. One example of the use of solder balls is to connect both a processor, such as a graphics processing unit (GPU) and a memory, such as a dynamic random access memory (DRAM), to different ends of a common wire in a PCB to create an electrical connection between the GPU and DRAM. Occasionally, during the fabrication process, one or more solder balls may fail to create a proper electrical connection between a particular device and a wire in the PCB. If a solder ball fails to form a proper electrical connection for the device, then the device is typically unable to properly transmit or receive signals, thereby compromising the functionality of the overall IC formed on the PCB.

Various conventional ways of detecting and locating failed electrical connections due to solder ball defects exist, but each approach has certain drawbacks. One approach to testing the integrity of solder ball connections is to use CPU-based software testing. One drawback to this approach is that CPU-based software testing requires adding both a special circuit to the IC as well as special timing windows. The addition of special circuitry is necessary in order to introduce the pulse signals required to detect defects. However, adding special circuitry to the IC is undesirable because special circuitry risks impeding the core operation of the IC. The addition of special timing windows is necessary because the timing of the software must be matched to the timing of the IC. However, special timing windows are undesirable because many ICs operate at high speeds, and creating timing windows in software to match IC speeds is difficult.

Another approach includes electronic probes. This approach involves physically attaching electronic probes to circuitry on the PCB in order to introduce signals into the circuitry to test the solder ball connections. One drawback to this approach is the difficulty in placing probes on the PCB due to the manner in which the PCB is constructed. More specifically, the circuit to be tested may be completely contained within the PCB, making it impracticable or even impossible to access the circuit with physical probes.

Yet another approach to testing for solder ball defects is reheating of the solder balls under the GPU and DRAM through simple trial and error. In other words, if a solder ball defect is detected somewhere on the PCB, a side containing either the GPU or the DRAM is chosen for repair, without knowing whether that side is actually the side that contains the defective solder ball connection. The solder balls on the chosen side are heated in order to induce the solder ball to reflow to establish a proper connection with the relevant wire on the PCB. However, the trial and error approach may result in unnecessary heating of a properly functioning side, and subsequent heating of a defective side. Heating the solder balls may unavoidably heat the PCB, which is undesirable since heating may cause the shape of the PCB to become distorted and thus damage the PCB.

As the foregoing illustrates, there is a need in the art for a more effective way of testing ICs to determine more precisely where solder ball connection defects exist.

### SUMMARY OF THE INVENTION

One embodiment of the present invention sets forth a method for detecting one or more defective solder ball connections. The method includes configuring, via logic included within a processing unit, a transmitter pad to transmit a pulse signal and to receive a pulse reflection, transmitting the pulse signal, and determining whether a pulse reflection is received in response to the pulse signal. If a pulse reflection is received, then the pulse reflection is analyzed to identify where a defective solder ball connection is located. If a pulse reflection is not received, then the outcome of not detecting that a defective solder ball connection is indicated.

One advantage of the disclosed method is that the method provides a more precise location of where solder ball connection defects exist, thereby avoiding unnecessary heating of the PCB, GPU and/or DRAM.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an IC system configured to implement one or more aspects of the present invention;

FIG. 2 is a conceptual illustration of a subsystem that is configured to transmit and receive pulse signals, according to one embodiment of the invention;

FIGS. 3A and 3B are conceptual illustrations of an IC system configured for detecting a defective solder ball connection, according to one embodiment of the invention;

FIG. 4 is a flow diagram of method steps for detecting a defective solder ball connection, according to one embodiment of the invention;

FIGS. 5A and 5B are conceptual illustrations of a system configured for detecting a defective solder ball connection, according to another embodiment of the invention;

FIG. 6 is a flow diagram of method steps for detecting a solder ball connection, according to another embodiment of the invention; and

FIG. 7 is a conceptual illustration of a subsystem that is configured to transmit and receive pulse signals, according to yet another embodiment of the invention.

### DETAILED DESCRIPTION

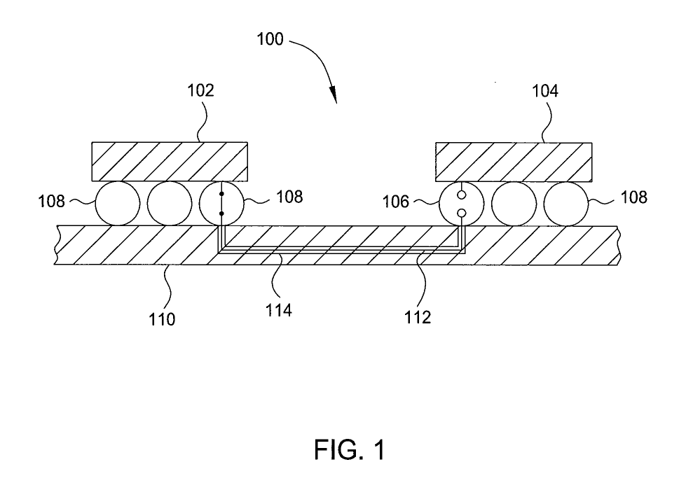

FIG. 1 illustrates an IC system configured to implement one or more aspects of the present invention. As shown, IC system 100 includes, without limitation, a graphics processing unit (GPU) 102 and a dynamic random access memory (DRAM) 104, both of which are coupled to printed circuit board (PCB) 110 by solder balls 108. GPU 102 is electrically connected to DRAM 104 by an electrical connection 112. While electrical connections, such as electrical connection 112, exist for each solder ball 108 that connects the GPU 102 to DRAM 104 through a PCB wire 114, only one electrical connection is shown for clarity. Solder ball 106 is largely similar to solder balls 108 except that solder ball 106 has failed to create an electrical connection, as represented by the open circuit pictured within solder ball 106. Solder balls fail to create electrical connections for a number of reasons, including contaminants that impede a proper electrical connection as well as improper heating of the solder ball or cracking of the solder ball. GPU 102 and DRAM 104 may utilize numerous solder balls 108, making the process of locating a defective solder ball such as solder ball 106 difficult. Embodiments of the invention, as discussed below, provide a hardware-based approach for detecting where such defective solder ball connections are located.

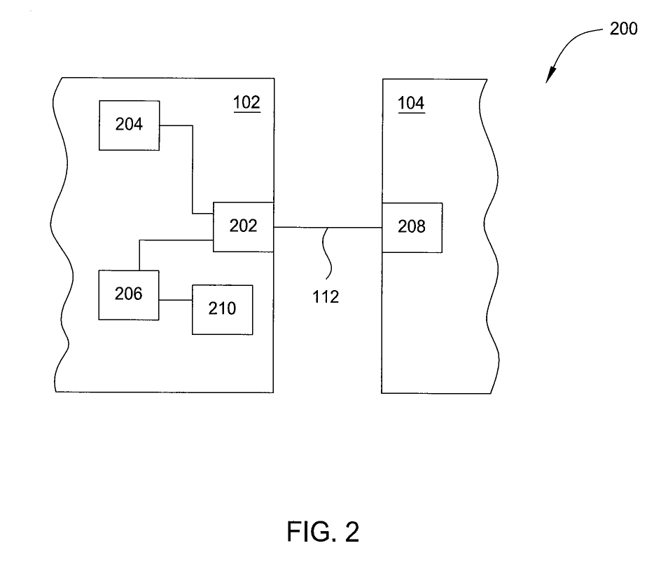

FIG. 2 is a conceptual illustration of a subsystem 200 that is configured to transmit and receive pulse signals, according to one embodiment of the invention. As shown, subsystem 200 includes, without limitation, GPU 102 and DRAM 104 of FIG. 1 as well as a GPU pad 202, transmit logic 204, receive logic 206, analysis logic 210, and a DRAM pad 208. In one embodiment, GPU pad 202, transmit logic 204, receive logic 206 and analysis logic 210 are all located within GPU 102, and DRAM pad 208 is located within DRAM 104. GPU pad 202 is connected to DRAM pad 208 by electrical connection 112, and by way of example, GPU pad 202 may be an analog amplifier configured to generate an amplified output signal for transmission to DRAM pad 208.

As previously described herein, if the path of electrical connection 112 includes a defective solder ball connection, such as solder ball 106, then electrical connection 112 is not able to properly transfer electrical signals from GPU pad 202 to DRAM pad 208. Accordingly, transmit logic 204 is configured to cause GPU pad 202 to transmit a pulse signal having a predetermined shape across electrical connection 112 in order to detect the location of the defective solder ball connection using time domain reflectometry. Receive logic 206 is configured to cause GPU pad 202 to receive a reflection of the pulse signal that may result in response to GPU pad 202 transmitting the initial pulse signal. Analysis logic 210 is configured to analyze the pulse signal reflection received by receive logic 206 and determine whether the solder ball connection defect is located on the GPU-side of subsystem 200 or the DRAM-side of subsystem 200 based on the amount of delay in the pulse signal reflection. For example, if GPU pad 202 transmits a pulse signal that causes GPU pad 202 to receive a pulse signal reflection after a relatively large delay, then one can conclude that the solder ball connection defect is on the DRAM-side of subsystem 200. By contrast, if a pulse signal reflection is received by GPU pad 202 after a relatively short delay, then one can conclude that the solder ball connection defect is on the GPU-side of subsystem 200. In this manner, the locations of solder ball connection defects, whether the defect is in a solder ball attached to GPU 102 or in a solder ball attached to DRAM 104, may be determined.

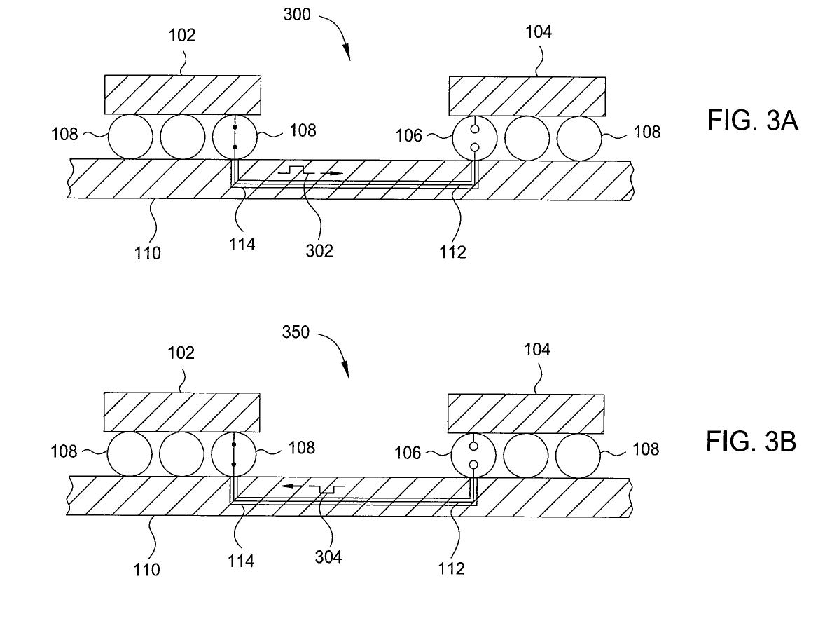

FIGS. 3A and 3B are conceptual illustrations of an IC system configured for detecting a defective solder ball connection, according to one embodiment of the invention. IC system 300 is largely similar to IC system 100, and includes similar elements. As shown, GPU pad 202 is configured to transmit a pulse signal 302 along electrical connection 112 towards DRAM pad 208. By way of example and not limitation, pulse signal 302 is illustrated as a square wave, although persons skilled in the art will understand that a pulse signal having a predetermined shape may be of a different shape. When pulse signal 302 encounters a defect, such as defective solder ball 106, pulse signal 302 may partially bounce off of the defect, generating a pulse reflection 304, as illustrated in IC system 350. By way of example, defective solder ball 106 is associated with DRAM 104, and causes a pulse reflection 304 after a relatively large delay between the point in time in which pulse signal 302 was originally transmitted by GPU pad 202, and the point in time in which pulse reflection 304 is received by GPU pad 202. As described above, a relatively large delay is indicative of a defective solder ball on the DRAM side of subsystem 200.

IC systems 300 and 350 illustrate a non-protocol implementation for detecting a defective solder ball connection, according to one embodiment of the invention. According to the non-protocol implementation, transmit logic 204 configures GPU pad 202 to transmit a pulse signal 302 having a predetermined shape, and no additional signal is sent. In other words, the non-protocol implementation involves configuring GPU pad 202 to send only pulse signal 302, and does not include sending instructions to DRAM before or after pulse signal 302. Furthermore, one of two scenarios may occur in response to the transmission of pulse signal 302. If a defect is encountered, pulse signal 302 may generate pulse reflection 304. If no defect is encountered, then a reflection is not expected. In both scenarios under the non-protocol implementation, no instructions are sent by GPU 102 to DRAM 104, and thus no acknowledgement signal from DRAM 104 is expected.

In sum, after GPU pad 202 transmits pulse signal 302, receive logic 206 configures GPU pad 202 to receive pulse reflection 304. If there is a solder ball defect, then pulse reflection 304 is generated, and analysis logic 210 is configured to analyze the pulse reflection 304 received by receive logic 206. Analysis logic 210 is configured to determine whether the defective solder ball is located on GPU 102 or DRAM 104 based on the amount of delay in the pulse signal reflection. However, if no pulse reflection occurs after pulse signal 302 is sent, then the lack of pulse reflection is indicative of properly functioning solder ball connections relative to both GPU 102 and DRAM 104.

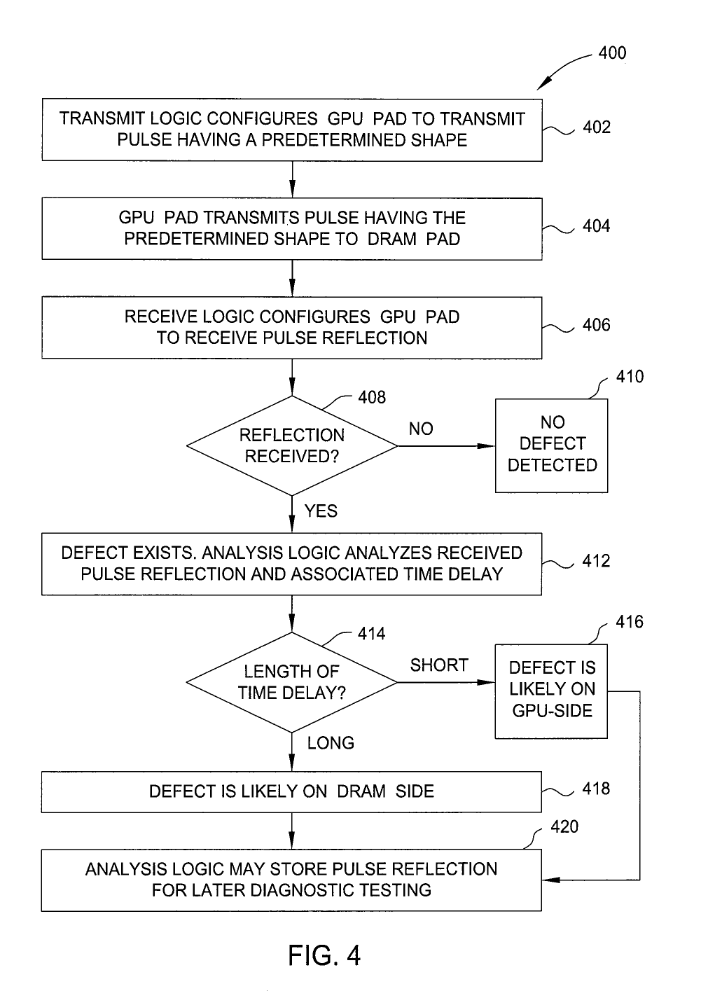

FIG. 4 is a flow diagram of method steps for detecting a defective solder ball connection, according to one embodiment of the invention. Although the method steps are described in conjunction with FIGS. 1-3B, persons skilled in the art will understand that any system configured to perform the method steps, in any order, falls within the scope of the present invention. Further, those skilled in the art will recognize that the method steps of FIG. 4 are directed towards the non-protocol implementation described above in conjunction with FIGS. 3A-3B.

As shown, a method 400 begins at step 402, where transmit logic 204 configures GPU pad 202 to transmit pulse signal 302 having a predetermined shape. Transmit logic 204 configures GPU pad 202 to transmit only pulse signal 302, and does not configure GPU pad 202 to transmit any other signals or instructions to DRAM 104. At step 404, GPU pad 202 transmits pulse signal 302 having a predetermined shape to DRAM pad 208. At step 406, receive logic 206 configures GPU pad 202 to receive a pulse reflection 304. Again, in the non-protocol embodiment of the invention, no acknowledgment signal from DRAM pad 208 is expected after pulse signal 302 is sent. At step 408, receive logic 206 determines whether a pulse reflection 304 was received by GPU pad 202. At step 410, if no pulse reflection is received, then one can conclude that no solder ball defect exists on either GPU 102 or DRAM 104. At step 412, if a pulse reflection is received, then a defect exists along electrical connection 112. In such a case, analysis logic 210 analyzes the received pulse reflection 302 and associated time delay between the point in time in which pulse signal 302 was originally transmitted by GPU pad 202 and the point in time in which pulse reflection 304 is received by GPU pad 202. At step 414, the analysis logic 210 determines whether the time delay was relatively short or relatively long. At step 416, if the time delay was relatively short, then analysis logic 210 concludes that the solder ball defect is associated with GPU 102. At step 418, if the time delay was relatively long, then analysis logic 210 concludes that the solder ball defect is associated with DRAM 104. At step 420, the analysis logic may store the pulse reflection 304 for later diagnostic testing.

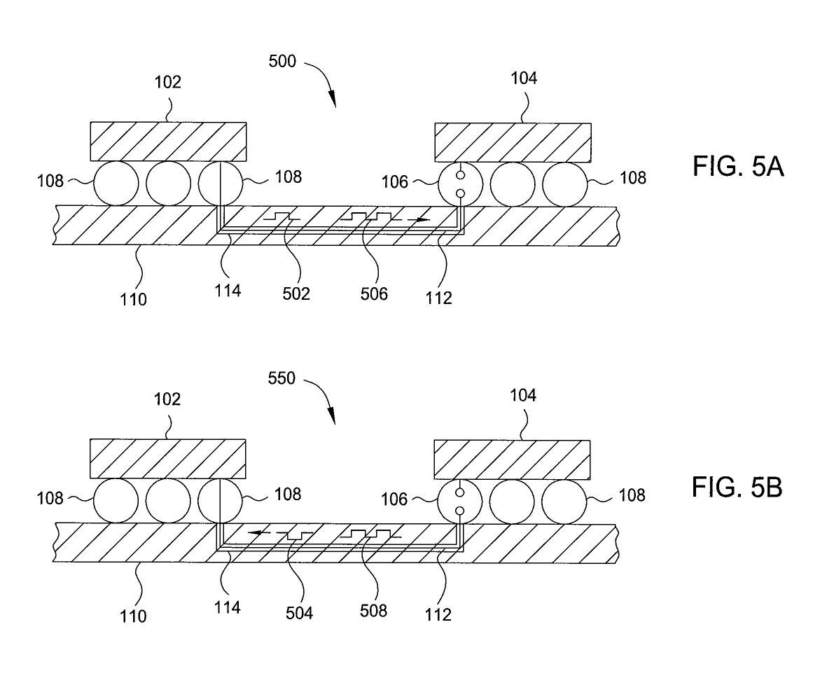

FIGS. 5A and 5B are conceptual illustrations of an IC system configured for detecting a defective solder ball connection, according to one embodiment of the invention. IC system 500 is largely similar to IC system 100, and includes similar elements. As shown, GPU pad 202 is configured to transmit a pulse signal 502 to DRAM pad 208. By way of example and not limitation, pulse signal 502 is illustrated as a square wave, although persons skilled in the art will understand that a pulse signal having a predetermined shape may be of a different shape. Again, when pulse signal 502 encounters a defect, such as defective solder ball 106, pulse signal 502 may partially bounce off of the defect, generating a pulse reflection 504, as illustrated in IC system 550. By way of example, defective solder ball 106 is associated with DRAM 104, and causes a pulse reflection 504 after a relatively large delay between the point in time in which pulse signal 502 was originally transmitted by GPU pad 202 and the point in time in which pulse reflection 304 is received by GPU pad 202. As described above, a relatively large delay is indicative of a defective solder ball on the DRAM side of subsystem 200.

IC systems 500 and 550 illustrate a protocol implementation for detecting a defective solder ball connection, according to one embodiment of the invention. According to the protocol implementation, transmit logic 204 configures GPU pad 202 to transmit configuration instructions 506 in close proximity to pulse signal 502. By way of example and not limitation, configuration instructions 506 are illustrated as preceding pulse signal 502, although persons skilled in the art will understand that pulse signal 502 may be embedded within configuration instructions 506. Configuration instructions 506 are employed to instruct DRAM pad 208 to send an acknowledgment signal 508 upon receiving configuration instructions 506.

In sum, after GPU pad 202 transmits pulse signal 502, receive logic 206 configures GPU pad 202 to receive both pulse reflection 504 and acknowledgment signal 508. Again, by way of example and not limitation, acknowledgment signal 508 is illustrated as following pulse reflection 502, although persons skilled in the art will understand that pulse reflection 502 may occur before, after or within acknowledgment signal 508. Among other things, the position of the pulse reflection relative to the acknowledge signal 508 may depend on the location of the defect along electrical connection 112. Furthermore, persons skilled in the art will understand that a defective solder ball such as solder ball 106 may disrupt the transmission of configuration instructions 506 along electrical connection 112. Such disruption may cause DRAM pad 208 to fail to transmit acknowledgment signal 508 in response to configuration instructions 506. Therefore, one possibility is that only pulse reflection 504 may occur, despite the fact that both pulse signal 502 and configuration instructions 506 were sent to DRAM pad 208. If there is a solder ball defect, then pulse reflection 504 is generated, and a combination of pulse reflection 504 and acknowledge signal 504 is received, and analysis logic 210 is configured to analyze the pulse reflection 504 and acknowledgment signal 508 received by receive logic 206. Analysis logic 210 is configured to determine whether the defective solder ball is located on GPU 102 or DRAM 104 based on the amount of delay in the pulse signal reflection. However, if no pulse reflection occurs after pulse signal 502 is sent, and only an acknowledgment signal 508 is received, then the lack of pulse reflection 504 is indicative of properly functioning solder ball connections associated with both GPU 102 and DRAM 104.

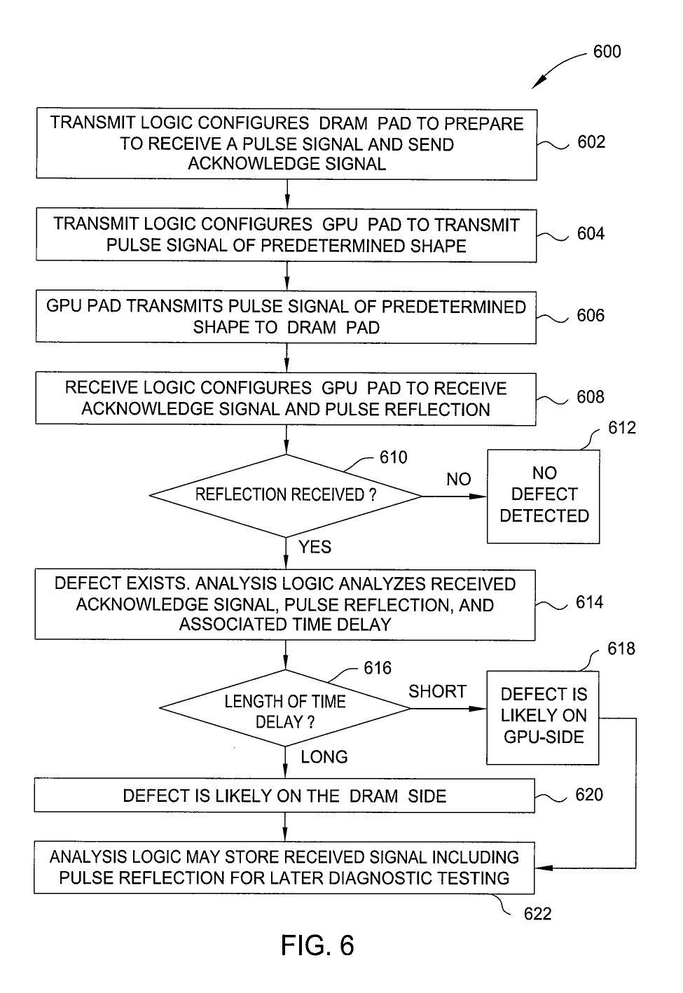

FIG. 6 is a flow diagram of method steps for detecting a defective solder ball connection, according to one embodiment of the invention. Although the method steps are described in conjunction with FIGS. 1-5B, persons skilled in the art will understand that any system configured to perform the method steps, in any order, falls within the scope of the present invention. Further, those skilled in the art will recognize that the method steps of FIG. 6 are directed towards the protocol implementation described above in conjunction with FIGS. 5A-5B.

As shown, a method 600 begins at step 602, where transmit logic 204 configures DRAM pad 208 to prepare to receive a pulse signal 502 in combination with configuration instructions 506. One function of configuration instructions 506 is that configuration instructions 506 configure DRAM pad 208 to transmit an acknowledgment signal 508 in response to configuration instructions 506. At step 604 transmit logic 204 configures GPU pad 202 to transmit pulse signal 502 having a predetermined shape. At step 606, GPU pad 202 transmits pulse signal 502 having a predetermined shape to DRAM pad 208. At step 608, receive logic 206 configures GPU pad 202 to receive a pulse reflection 504 in combination with acknowledgment signal 508. At step 610, receive logic 206 determines whether a pulse reflection 504 was received by GPU pad 202. At step 612, if no pulse reflection is received, then one can conclude that no solder ball defect exists on either GPU 102 or DRAM 104. At step 614, if a pulse reflection is received, then a defect exists along electrical connection 112. In such a case, analysis logic 210 analyzes the received pulse reflection 302, acknowledge signal 508, and associated time delay between the point in time in which pulse signal 502 was originally transmitted by GPU pad 202, and the point in time in which pulse reflection 504 is received by GPU pad 202. At step 616, the analysis logic 210 determines whether the time delay was relatively short or relatively long. At step 618, if the time delay was relatively short, then analysis logic 210 concludes that the solder ball defect is associated with GPU 102. At step 418, if the time delay was relatively long, then analysis logic 210 concludes that the solder ball defect is associated with DRAM 104. At step 622, the analysis logic may store the pulse reflection 504 and acknowledge signal 508 for later diagnostic testing.

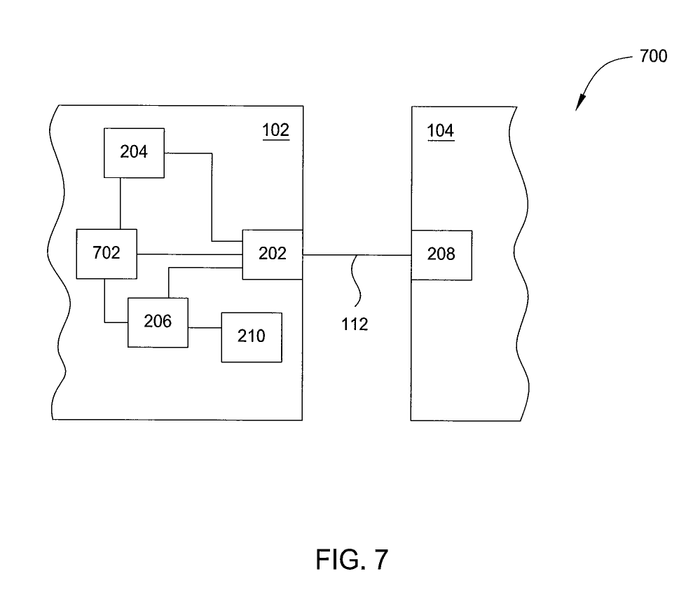

FIG. 7 is a conceptual illustration of a subsystem 700 that is configured to transmit and receive pulse signals, according to yet another embodiment of the invention. As shown, subsystem 700 is largely similar to subsystem 200, but also includes setup logic 702. In previous embodiments of the invention, transmit logic 204 configures GPU pad 202 to transmit a pulse signal having a predetermined shape. Neither the amplitude nor shape of the pulse signal is substantially modified from that predetermined shape. However, in some applications, being able to adjust the characteristics of the pulse signal generated by GPU pad 202, including the amplitude and/or shape of the pulse signal, would be desirable. As described in greater detail below, set up logic 702 enables such modifications.

Consider the following example. Electrical connection 112 contains a defective solder ball 106 with low reflectivity. Reflectivity is defined herein to be the quality of pulse signal reflectance of a circuit defect when employing time domain reflectometry. The low reflectivity of solder ball 106 causes solder ball 106 to be difficult to detect when using a pulse signal 302 having a predetermined shape. Similar to method 400, pulse signal 302 having a predetermined shape is transmitted by GPU pad 202 and encounters defective solder ball 106. However, the poor reflectivity of defective solder ball 106 causes pulse signal 302 to generate a weak pulse reflection 304 with undesirable characteristics such as low amplitude and/or undesirable shape. The undesirable characteristics of defective solder ball 106 cause GPU pad 202 to receive a weak pulse reflection 304 that is difficult to detect and analyze. Consequently, analysis logic 210 is not able to properly detect and analyze pulse reflection 304, potentially leading one to incorrectly conclude that the solder balls along electrical connection 112 are functional, despite of the existence of defective solder ball 106.

Accordingly, one embodiment of the invention employs setup logic 702, which is configured to cause GPU pad 202 to customize various characteristics of a pulse signal, such as the shape and/or amplitude of the pulse signal. By customizing a combination of the shape and amplitude of pulse signal, the pulse signal may generate a pulse reflection that can be easier to detect and analyze. Both protocol and non-protocol techniques described above may be implemented with setup logic 702.

Returning now to the above example, setup logic 702 can be configured to increase of the amplitude of pulse signal 302 and/or adjust the shape of pulse signal 302, as desired, to create customized pulse signal 302. Similar to method 400, GPU pad 202 then transmits customized pulse signal 302 along electrical connection 112. Customized pulse signal 302 encounters defective solder ball 106, which has low reflectivity. In contrast to the above example, customized pulse signal 302 is capable of generating a strong pulse reflection 304 despite the low reflectivity of defective solder ball 106. Furthermore, strong pulse reflection 304 has desirable characteristics, including a higher amplitude and/or more desirable shape, relative to weak pulse reflection 304. Unlike weak pulse reflection 304, a strong pulse reflection 304 is easier to detect and analyze. Thus, analysis logic 210 is able to properly detect and analyze strong pulse reflection 304, allowing one to properly conclude that solder ball 106 is defective, despite the low reflectivity of defective solder ball 106.

In addition to the foregoing, setup logic 702 can also cause a pulse signal 302 to be customized such that pulse signal 302 has the ability to travel paths along electrical connection 112 of varying distances. Finally, those skilled in the art will appreciate that setup logic 702 can be configured to cause the customization of other pulse signal characteristics instead of or in combination with amplitude and/or shape, including, without limitation, pulse timing and repeated pulses, in order to customize pulse signals to compensate for various types of solder ball defects. In yet other embodiments, the pulse signals 302 may be customized via setup logic 702 with any characteristics, and all technically feasible pulse signal characteristics fall within the scope of the present invention. In alternative embodiments, a power management unit (PMU) or a central processing unit (CPU) may configure the GPU pad 202 to transmit a customized pulse signal 302 in lieu of the setup unit 702.

In sum, techniques are disclosed for locating defective solder ball connections within an integrated circuit disposed on a printed circuit board. In the non-protocol version of the technique, transmit logic configures the pad on the GPU-side to send a pulse having a predetermined shape into DRAM, and receive logic configures the pad to receive a reflection of the pulse. If a reflection is received, then the reflection is analyzed by analysis logic which determines where the defect is located based on the amount of delay in the reflection. In one embodiment, if a transmitted pulse causes a reflection to occur with a large delay, then a defect is likely on the side further away from the location of the transmitted pulse. By way of example, if a pulse is sent and a reflection is detected after a relatively long period of time, then the reflection is indicative of a problem in DRAM. The opposite would be true if the reflection is detected shortly after the pulse is sent. The analysis logic may also store the reflection for subsequent diagnostic testing.

In the protocol version of the technique, the transmit logic configures DRAM to first prepare to receive a pulse and then send an acknowledgment signal back to the pad. The transmit logic then configures a pad to send a pulse having a predetermined shape into DRAM, and receive logic configures the pad to receive an acknowledgment signal in return. If a pulse reflection is detected within the acknowledgment signal, then the analysis logic analyzes the pulse reflection to determine where the defect is located based on the amount of delay in the reflection. The analysis logic may also store the returned signal for subsequent diagnostic testing.

Both protocol and non-protocol techniques may be implemented with setup logic that overrides the default pulse characteristics programmed into the transmit logic. The setup logic configures the pad to alter the programmed characteristics of the pulse, including amplitude and shape. Altering the amplitude and shape of a pulse may create a pulse reflection that is easier to detect and analyze.

One advantage of the disclosed techniques is that solder ball defects may be detected more accurately than in the trial and error approach, which in turn may reduce the amount of heat distortion damage to the PCB, GPU and/or DRAM. Another advantage of the disclosed techniques is that physically probing circuits for defects is unnecessary. Thus difficulty of placing probes is avoided. Another advantage of the disclosed techniques is that CPU-based testing may be avoided. Thus, the use of special timing windows may be avoided. Yet another advantage of the disclosed techniques is that the disclosed technique may detect defective solder balls more quickly than the abovementioned alternative testing methods, thus saving time when conducting solder ball defect testing.

While the foregoing is directed to embodiments of the present invention, other and further embodiments of the invention may be devised without departing from the basic scope thereof. Persons skilled in the art will understand that subsystems designed according to the disclosed techniques may be included and implemented in any type of IC connected to PCB wires using solder balls. For example, the disclosed techniques may be used to test connections between a central processing unit and system memory and may be used to test the connections of any devices to any bus or high-speed bus within a computer system.

Therefore, the scope of the embodiments of the invention is determined by the claims that follow.

What is claimed is:

1. A method for detecting one or more defective solder ball connections, the method comprising:
configuring, via logic included within a processing unit, a transmitter pad to transmit a pulse signal and to receive a pulse reflection,
transmitting the pulse signal,
determining whether a pulse reflection is received in response to the pulse signal; and
if a pulse reflection is received, then analyzing the pulse reflection to identify where a defective solder ball connection is located; or
if a pulse reflection is not received, then indicating that a defective solder ball connection has not been detected.

2. The method of claim 1, wherein analyzing the pulse reflection comprises determining an amount of delay between the point in time when the pulse signal is transmitted and the point in time when the pulse reflection is received.

3. The method of claim 2, wherein a small amount of delay indicates that the defective solder ball connection is proximate to the processing unit, and a large amount of delay indicates that the defective solder ball connection is proximate to a device that receives the pulse signal.

4. The method of claim 3, wherein the processing unit comprises a graphics processing unit, and the device that receives the pulse signal comprises a memory device.

5. The method of claim 1, further comprising transmitting a configuration instruction along with the pulse signal.

6. The method of claim 5, wherein the pulse reflection is received along with an acknowledgment signal.

7. The method of claim 6, further comprising specifying one or more characteristics of the pulse signal.

8. The method of claim 7, wherein the one or more characteristics includes a shape of the pulse signal.

9. The method of claim 8, wherein the one or more characteristics includes amplitude of the pulse signal.

10. A subsystem configured to detect defective solder ball connections, the subsystem comprising:
a transmitter pad configured via transmit logic to transmit a pulse signal and configured via receive logic to receive a pulse reflection; and
an analysis logic unit configured to:
determine whether a pulse reflection is received in response to the pulse signal, and
if a pulse reflection is received, then
analyze the pulse reflection, and
identify where a defective solder ball connection is located, or
if a pulse reflection is not received, then
indicate that a defective solder ball connection has not been detected.

11. The subsystem of claim 10, wherein the analysis logic unit is further configured to determine an amount of delay between the point in time when the pulse signal is transmitted and the point in time when the pulse reflection is received.

12. The subsystem of claim 11, wherein a small amount of delay indicates that the defective solder ball connection is proximate to a processing unit that transmits the pulse signal, and a large amount of delay indicates that the defective solder ball connection is proximate to a device that receives the pulse signal.

13. The subsystem of claim 12, wherein the processing unit comprises a graphics processing unit, and the device that receives the pulse signal comprises a memory device.

14. The subsystem of claim 10, wherein the transmitter pad is further configured to send a configuration instruction along with the pulse signal.

15. The subsystem of claim 14, wherein the transmitter pad is further configured to receive the pulse reflection along with an acknowledgment signal.

16. The subsystem of claim 15, further comprising set-up logic that is further configured to specify one or more characteristics of the pulse signal.

17. The subsystem of claim 16, wherein the one or more characteristics includes a shape of the pulse signal.

18. The subsystem of claim 17, wherein the one or more characteristics includes amplitude of the pulse signal.

19. A computing device configured to detect defective solder ball connections, the computing device comprising:
a transmitter pad configured via transmit logic to transmit a pulse signal and configured via receive logic to receive a pulse reflection; and
an analysis logic unit configured to:
determine whether a pulse reflection is received in response to the pulse signal, and
if a pulse reflection is received, then
analyze the pulse reflection, and
identify where a defective solder ball connection is located, or
if a pulse reflection is not received, then
indicate that a defective solder ball connection has not been detected.

20. The computing device of claim 19, wherein the analysis logic unit is further configured to analyze the pulse reflection to determine an amount of delay between the point in time when the pulse signal is transmitted and the point in time when the pulse reflection is received in order to determine a location of the defective solder ball connection.
